(19) United States
(12) Patent Application Publication
(10) Pub. No.: US 2025/0366133 A1
(43) Pub. Date: Nov. 27, 2025

(54) SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: RUNG HUNG HSUEH, KAOHSIUNG CITY (TW); YUNG HAN CHEN, TAINAN CITY (TW); PIN CHI HUANG, TAINAN CITY (TW)

(21) Appl. No.: 18/674,956

(22) Filed: May 27, 2024

(51) Int. Cl. H01L 29/40; H01L 29/66; H01L 29/78

(52) U.S. Cl. CPC H10D 64/112; H10D 30/0281; H10D 30/65; H10D 64/01

(57) ABSTRACT

A semiconductor device and method of manufacturing the same are provided. The semiconductor device includes a substrate, a gate electrode, a source/drain feature, an interlayer dielectric (ILD), a first field plate holder, and a first field plate. The gate electrode is disposed on the substrate. The source/drain feature is disposed within the substrate and defines a drift region within the substrate. The ILD covers the gate electrode and the substrate. The first field plate holder penetrates the ILD and is disposed over the drift region. The first field plate is disposed on the first field plate holder.

### BACKGROUND

Technological advances in semiconductor integrated circuit (IC) materials, design, processing, and manufacturing have enabled the continual reduction in size of IC devices, where each generation has smaller and more complex circuits than the previous generation.

As semiconductor circuits composed of devices such as metal-oxide-semiconductor field-effect transistors (MOSFETs) are adapted for high voltage applications, such as in lateral diffusion metal-oxide-semiconductor (LDMOS) devices, problems arise with respect to decreasing voltage performance as the downscaling continues with advanced technologies. Therefore, a new semiconductor device is required.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1 illustrates a cross-sectional view of a semiconductor device, in accordance with some embodiments of the present disclosure.

FIG. 2 illustrates a partial enlarged view of the semiconductor device as shown in FIG. 1.

FIG. 3 illustrates a cross-sectional view of a semiconductor device, in accordance with some embodiments of the present disclosure.

FIG. 4 illustrates a cross-sectional view of a semiconductor device, in accordance with some embodiments of the present disclosure.

FIG. 5 illustrates a cross-sectional view of a semiconductor device, in accordance with some embodiments of the present disclosure.

FIG. 6 illustrates a cross-sectional view of a comparative semiconductor device, in accordance with some embodiments of the present disclosure.

FIG. 7A, FIG. 7B, FIG. 7C, FIG. 7D, FIG. 7E, and FIG. 7F illustrate various stages of manufacturing a semiconductor device, in accordance with some embodiments of the present disclosure.

FIG. 8 is a flow chart illustrating a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may be also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and the attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

In some embodiments, semiconductor devices 1a to 1d are provided. Each of the semiconductor devices 1a to 1d can be a high voltage semiconductor device. Each of the semiconductor devices 1a to 1d can be an n type high-voltage device, but the disclosure is not limited thereto. In some embodiments, each of the semiconductor devices 1a to 1d can be referred to as a laterally-diffused MOS (LDMOS) transistor device, a high-voltage laterally-diffused MOS (HV LDMOS) transistor device, a high-voltage extended-drain MOS (HV EDMOS) transistor device, or any other device.

In some embodiments of the present disclosure, a field plate holder(s) is provided to accommodate a field plate(s). The filed plate holder is configured to prevent an over-etching that could cause the field plate to be contact with the substrate. In other embodiments, the field plate holder is utilized to control, adjust, and/or modify the depth of the field plate. Therefore, the breakdown voltage capability of a semiconductor device is enhanced.

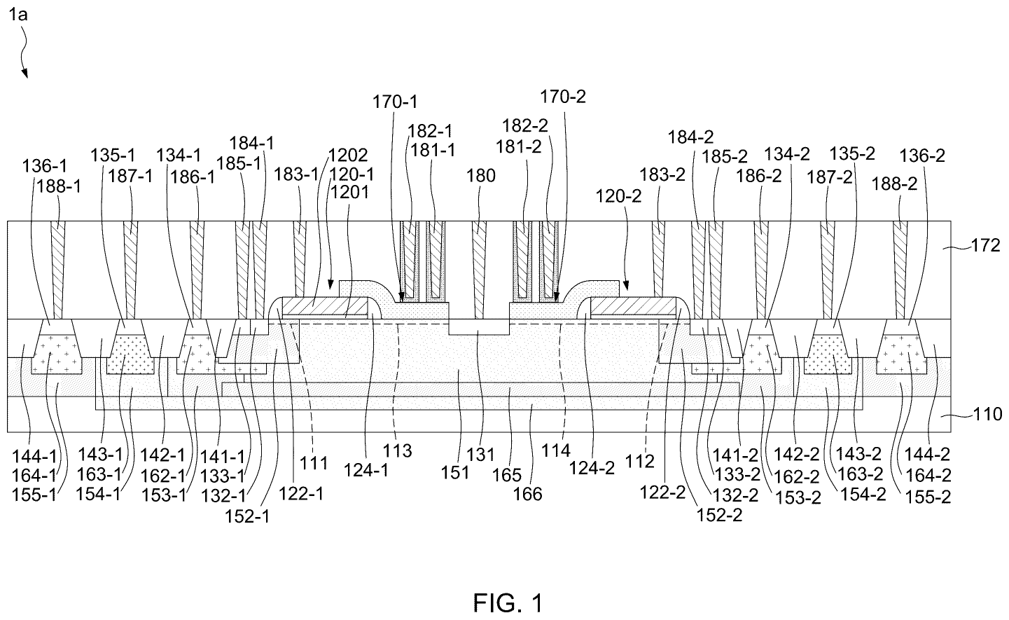

FIG. 1 illustrates a cross-sectional view of a semiconductor device 1a, in accordance with some embodiments of the present disclosure.

In some embodiments, the semiconductor device 1a includes a substrate 110. The substrate 110 includes a semiconductor substrate, such as a bulk semiconductor, a semiconductor-on-insulator (SOI) substrate, or the like, which may be doped (e.g., with a p type or an n type dopant) or undoped. The substrate 110 can include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable material; or a combination thereof. In some embodiments, the alloy semiconductor substrate includes a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy can be mechanically strained by another material in contact with the SiGe alloy. In some embodiments, the substrate 110 may have a multilayer structure, or the substrate 110 may include a multilayer compound semiconductor structure.

In some embodiments, the semiconductor device 1a includes gate structures 120-1 and 120-2. Each of the gate structures 120-1 and 120-2 is disposed on the substrate 110. Each of the gate structures 120-1 and 120-2 includes a gate dielectric 1201 and a gate electrode 1202.

The gate dielectric 1201 may have a single layer or a multi-layer structure. In some embodiments, the gate dielectric 1201 is a multi-layer structure that includes an interfacial layer and a high-k (dielectric constant greater than 4) dielectric layer. The interfacial layer can include dielectric material such as silicon oxide, silicon nitride, silicon oxynitride, other dielectric material, or a combination thereof. The high-k dielectric layer can include high-k dielectric material such as HfO₂, HfSiO, HfSiON, HfTaO, HfTiO, HfZrO, other suitable high-k dielectric materials, or a combination thereof. In some embodiments, the high-k dielectric material can further be selected from metal oxides, metal nitrides, metal silicates, transition metal-oxides, transition metal-nitrides, transition-metal silicates, metal oxynitrides, metal aluminates, and combinations thereof.

The gate electrode 1202 is disposed on the gate dielectric 1201. The gate electrode 1202 includes polysilicon, silicon-germanium, and at least one metallic material including elements and compounds such as Mo, Cu, W, Ti, Ta, TiN, TaN, NiSi, CoSi, or other suitable conductive materials known in the art. In some embodiments, the gate electrode 1202 includes a work function metal layer that provides a metal gate with an n type-metal work function or p type-metal work function. The p type-metal work function materials include materials such as ruthenium, palladium, platinum, cobalt, nickel, conductive metal oxide, or other suitable materials. The n type-metal work function materials include materials such as hafnium zirconium, titanium, tantalum, aluminum, metal carbides (e.g., hafnium carbide, zirconium carbide, titanium carbide, and aluminum carbide), aluminides, or other suitable materials.

In some embodiments, the semiconductor device 1a includes spacers 122-1 and 124-1. The spacers 122-1 and 124-1 are disposed on two opposite sides of the gate structure 120-1. Each of the spacers 122-1 and 124-1 includes a single layer structure or a multilayered structure. Each of the spacers 122-1 and 124-1 includes silicon oxide, silicon nitride, silicon oxynitride, other dielectric material, or a combination thereof.

In some embodiments, the semiconductor device 1a includes spacers 122-2 and 124-2. The spacers 122-2 and 124-2 are disposed on two opposite sides of the gate structure 120-2. Each of the spacers 122-2 and 124-2 includes a single layer structure or a multilayered structure.

In some embodiments, the semiconductor device 1a includes doped regions 131, 132-1, 133-1, 134-1, 132-2, 133-2, and 134-2. The doped region 131 is disposed within the substrate 110. In some embodiments, the doped region 131 is disposed between the gate structures 120-1 and 120-2. In some embodiments, the doped region 131 may have a first conductive type. In some embodiments, the first conductive type is an n type. In some embodiments, n type dopants include arsenic (As), phosphorus (P), other group V elements, or any combination thereof. In some embodiments, the first conductive type is a p type. In some embodiments, p type dopants include boron (B), other group III elements, or any combination thereof. In some embodiments, the doped region 131 may serve as a common drain.

The doped region 132-1 is disposed within the substrate 110. The doped regions 132-1 and 131 may be disposed on two opposite sides of the gate structure 120-1. The doped regions 132-1 and 131 collectively define a source/drain (S/D) feature. The doped region 132-1 may have the first conductive type. The doped region 133-1 is disposed within the substrate 110. The doped region 133-1 is disposed adjacent to the doped region 132-1. In some embodiments, the doped region 133-1 is in contact with the doped region 132-1. The doped region 133-1 may have a second conductive type different from the first conductive type. The doped region 134-1 is disposed within the substrate 110. The doped region 134-1 is spaced apart from the doped region 133-1 by an isolation structure 141-1. In some embodiments, the doped region 134-1 may have the second conductive type. In some embodiments, the doped regions 132-1, 133-1, and 134-1 may be electrically connected to the same voltage supply and serve as a butted source.

The doped region 132-2 is disposed within the substrate 110. The doped regions 132-2 and 131 may be disposed on two opposite sides of the gate structure 120-2. The doped regions 132-2 and 131 collectively define a source/drain (S/D) feature. The doped region 132-2 may have the first conductive type. The doped region 133-2 is disposed within the substrate 110. The doped region 133-2 is disposed adjacent to the doped region 132-2. In some embodiments, the doped region 133-2 is in contact with the doped region 132-2. The doped region 133-2 may have the second conductive type. The doped region 134-2 is disposed within the substrate 110. The doped region 134-2 is spaced apart from the doped region 133-2 by an isolation structure 141-2. In some embodiments, the doped region 134-2 may have the second conductive type. In some embodiments, the doped regions 132-2, 133-2, and 134-2 may be electrically connected to the same voltage supply and serve as a butted source.

In some embodiments, the semiconductor device 1a includes doped regions 135-1 and 135-2. The doped region 135-1 is disposed within the substrate 110. The doped region 135-1 is spaced apart from the doped region 134-1 by an isolation structure 142-1. The doped region 135-1 may have the first conductive type. The doped region 135-2 is disposed within the substrate 110. The doped region 135-2 is spaced apart from the doped region 134-2 by an isolation structure 142-2. The doped region 135-2 may have the first conductive type. In some embodiments, each of the doped regions 135-1 and 135-2 may be configured to protect the semiconductor device 1a such that a greater voltage can be imposed on the semiconductor device 1a.

In some embodiments, the semiconductor device 1a includes doped regions 136-1 and 136-2. The doped region 136-1 is disposed within the substrate 110. The doped region 136-1 is spaced apart from the doped region 135-1 by an isolation structure 143-1. The doped region 136-1 may have the second conductive type. The doped region 136-2 is disposed within the substrate 110. The doped region 136-2 is spaced apart from the doped region 135-2 by an isolation structure 143-2. The doped region 136-2 may have the second conductive type. In some embodiments, each of the doped regions 136-1 and 136-2 may be configured to electrically connect to ground.

In some embodiments, the semiconductor device 1a further includes isolation structures 144-1 and 144-2. Each of the isolation structures 141-1, 142-1, 143-1, 144-1, 141-2, 142-2, 143-2, and 144-2 is disposed within the substrate 110 and spaced apart from each other in a cross-sectional view. In some embodiments, each of the isolation structures 141-1, 142-1, 143-1, 144-1, 141-2, 142-2, 143-2, and 144-2 is a shallow trench isolation (STI) as shown in FIG. 1. In other embodiments, the isolation structures 141-1, 142-1, 143-1, 144-1, 141-2, 142-2, 143-2, and 144-2 may include a structure of a local oxidization of silicon (LOCOS) structure, or any other suitable isolation structure.

In some embodiments, the semiconductor device 1a includes a well region 151. The well region 151 has the first conductive type. The doped region 131 is disposed within the well region 151. In some embodiments, the well region 151 can be referred to as a high-voltage n type well (HVNW) or a high-voltage p type well (HVPW).

In some embodiments, the semiconductor device 1a includes well regions 152-1 and 152-2. Each of the well regions 152-1 and 152-2 has the second conductive type. In some embodiments, each of the well regions 152-1 and 152-2 is partially disposed within the well region 151. The doped regions 132-1 and 133-1 are disposed within the well region 152-1. The doped regions 132-2 and 133-2 are disposed within the well region 152-2. In some embodiments, each of the well regions 152-1 and 152-2 can be referred to as a high-voltage p type well (HVPW) or a high-voltage n type well (HVNW).

In some embodiments, the well region 152-1 may define a channel region 111 laterally extending between the doped regions 132-1 and the well region 151. In some embodiments, the well region 152-2 may define a channel region 112 laterally extending between the doped region 132-2 and the well region 151. In some embodiments, the well region 151 may define a drift region 113 laterally extending between the doped regions 132-1 and 131. In some embodiments, the well region 151 may define a drift region 114 laterally extending between the doped region 132-2 and the doped region 131. During operation, a gate-source voltage (Vas) can be selectively applied to the gate structure 120-1 (or 120-2) relative to the doped region 132-1 (or 132-2), forming a conductive channel in the channel region 111 (or 112). While Vas is applied to form the conductive channel, a drain to source voltage (VDS) is applied to move charge carriers (e.g., holes or electrons) between the doped region 132-1 and 131 (or between 132-2 and 131). The channel region 111 (or 112) laterally extends from the doped region 132-1 (or 132-2) to an adjacent drift region 113. The drift region 113 (or 114) has a relatively low doping concentration, which provides for a higher resistance at high operating voltages. The gate structure 120-1 is disposed over the channel region 111. In some embodiments, the gate structure 120-1 may extend from over the channel region 111 to a position overlying a portion of the drift region 113. The gate structure 120-2 is disposed over the channel region 112. In some embodiments, the gate structure 120-2 may extend from over the channel region 112 to a position overlying a portion of the drift region 114.

In some embodiments, the semiconductor device 1a includes well regions 153-1 and 153-2. Each of the well regions 153-1 and 153-2 is disposed adjacent to the well region 151. Each of the well regions 153-1 and 153-2 has the second conductive type. In some embodiments, the doped region 134-1 is disposed within the well region 153-1. In some embodiments, the doped region 134-2 is disposed within the well region 153-2. In some embodiments, each of the well regions 153-1 and 153-2 can be referred to as a high-voltage p type well (HVPW) or a high-voltage n type well (HVNW).

In some embodiments, the semiconductor device 1a includes well regions 154-1 and 154-2. Each of the well regions 154-1 and 154-2 has the first conductive type. In some embodiments, the doped region 135-1 is disposed within the well region 154-1. In some embodiments, the doped region 135-2 is disposed within the well region 154-2. In some embodiments, each of the well regions 154-1 and 154-2 can be referred to as a high-voltage n type well (HVNW) or a high-voltage p type well (HVPW).

In some embodiments, the semiconductor device 1a includes well regions 155-1 and 155-2. Each of the well regions 155-1 and 155-2 has the second conductive type. In some embodiments, the doped region 136-1 is disposed within the well region 155-1. In some embodiments, the doped region 136-2 is disposed within the well region 155-2. In some embodiments, each of the well regions 155-1 and 155-2 can be referred to as a high-voltage p type well (HVPW) or a high-voltage n type well (HVNW).

In some embodiments, the semiconductor device 1a includes well regions 162-1 and 162-2. The well region 162-1 is partially disposed within the well region 151. The well region 162-1 is partially disposed within the well region 153-1. The well region 162-2 is partially disposed within the well region 151. The well region 162-2 is partially disposed within the well region 153-2. Each of the well regions 162-1 and 162-2 has the second conductive type. In some embodiments, each of the well regions 162-1 and 162-2 can be referred to as a shallow p-well region or a shallow n-well region.

In some embodiments, the semiconductor device 1a includes well regions 163-1 and 163-2. The well region 163-1 is disposed within the well region 154-1. The well region 163-2 is partially disposed within the well region 154-2. Each of the well regions 163-1 and 163-2 has the first conductive type. In some embodiments, each of the well regions 163-1 and 163-2 can be referred to as a shallow n-well region or a shallow p-well region.

In some embodiments, the semiconductor device 1a includes well regions 164-1 and 164-2. The well region 164-1 is disposed within the well region 155-1. The well region 164-2 is partially disposed within the well region 155-2. Each of the well regions 164-1 and 164-2 has the second conductive type. In some embodiments, each of the well regions 164-1 and 164-2 can be referred to as a shallow p-well region or a shallow n-well region.

In some embodiments, the semiconductor device 1a includes a well region 165. The well region 165 is disposed under the well region 151. The well region 165 has the second conductive type. In some embodiments, the well region 165 can be referred to as a deep p-well region or a deep n-well region.

In some embodiments, the semiconductor device 1a includes a doped region 166. The doped region 166 is disposed under the well region 165. The doped region 166 has the first conductive type. In some embodiments, the doped region 166 can be referred to as an n type buried layer or a p type buried layer.

In some embodiments, the semiconductor device 1a includes a shallow well region (not shown), with first conductive type, within the well region 151 and under the doped region 131.

In some embodiments, the semiconductor device 1a includes an interlayer dielectric (ILD) 172. The ILD 172 may cover the substrate 110, and gate structures 120-1 and 120-2. The ILD 172 may include a dielectric material, such as an oxide-containing material or other suitable materials. The oxide-containing material may include phosphosilicate glass (PSG), tetraethylorthosilicate (TEOS) oxide, un-doped silicate glass, silicon dioxide, doped silicon dioxide such as borophosphosilicate glass (BPSG), fused silica glass (FSG), boron doped silicon glass (BSG), another suitable dielectric material, or a combination thereof.

In some embodiments, the semiconductor device 1a includes conductive contacts 180, 181-1, 181-2, 182-1, 182-2, 183-1, 183-2, 184-1, 184-2, 185-1, 185-2, 186-1, 186-2, 187-1, 187-2, 188-1, and 188-2. The conductive contact 180 is electrically connected to the doped region 131. The conductive contact 180 is electrically connected to the doped region 131. The conductive contacts 181-1 and 182-1 are disposed over or vertically overlap the drift region 114. The conductive contacts 181-1 and 182-1 are disposed on the etch stop layer 170-1. Each of the conductive contacts 181-1 and 182-1 may function as a field plate, which is configured to act upon the electric field generated by the gate structure 120-1. The conductive contacts 181-1 and 182-1 may be configured to change distribution of the electric field generated by the gate structure 120-1 in the drift region 114, which enhances the internal electric field of the drift region 114 and increases the drift doping concentration of the drift region 114, thereby enhancing the breakdown voltage capability of the semiconductor device 1a. Although FIG. 1 illustrates that two field plates are disposed over the etch stop layer 170-1, the semiconductor devices 1a can include more field plates based on the requirements. The conductive contact 183-1 is electrically connected to the gate structure 120-1. The conductive contact 184-1 is electrically connected to the doped region 132-1. The conductive contact 185-1 is electrically connected to the doped region 133-1. The conductive contact 186-1 is electrically connected to the doped region 134-1. The conductive contact 187-1 is electrically connected to the doped region 135-1. The conductive contact 188-1 is electrically connected to the doped region 136-1.

The conductive contacts 181-2 and 182-2 are disposed over or vertically overlap the drift region 114. The conductive contacts 181-2 and 182-2 are disposed on the etch stop layer 170-2. Each of the conductive contacts 181-2 and 182-2 may function as a field plate. The conductive contact 183-2 is electrically connected to the gate structure 120-2. The conductive contact 184-2 is electrically connected to the doped region 132-2. The conductive contact 185-2 is electrically connected to the doped region 133-2. The conductive contact 186-2 is electrically connected to the doped region 134-2. The conductive contact 187-2 is electrically connected to the doped region 135-2. The conductive contact 188-2 is electrically connected to the doped region 136-2.

Each of the conductive contacts 180, 181-1 to 188-1, and 181-2 to 188-2 penetrates at least a portion of the ILD 172. Each of the conductive contacts 180, 181-1 to 188-1, and 181-2 to 188-2 may include a conductive material, such as copper (Cu), titanium (Ti), tungsten (W), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr), titanium nitride (TiN), tungsten nitride (WN), tantalum nitride (TaN), ruthenium (Ru) or a combination thereof.

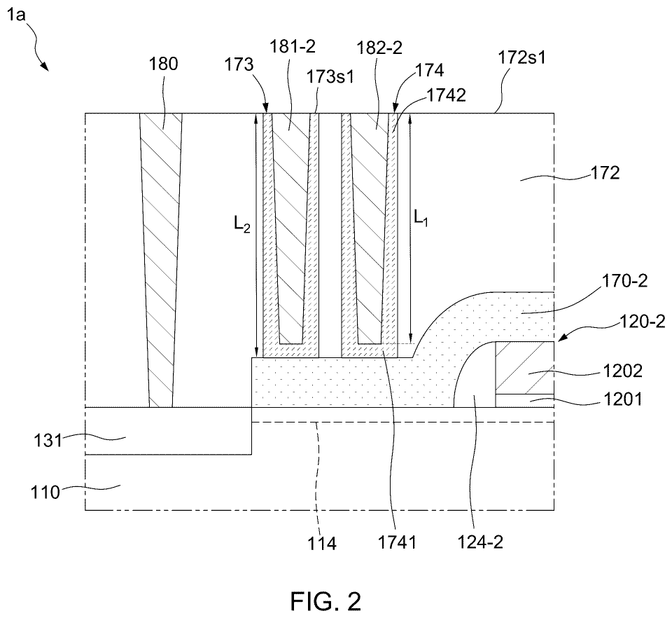

Referring to FIG. 2, which illustrates a partial enlarged view of the semiconductor device 1a. In some embodiments, the semiconductor device 1a includes field plate holders 173 and 174. In some embodiments, each of the field plate holders 173 and 174 may be configured to function as an etch stop structure to prevent over-etching that could cause a field plate to be in contact with the substrate 110. In some embodiments, each of the field plate holders 173 and 174 may be configured to modify, adjust, or control the length (or depth) of a field plate(s), thereby enhancing the breakdown voltage capability of the semiconductor device 1a. In some embodiments, each of the field plate holders 173 and 174 is embedded within or surrounded by the ILD 172. In some embodiments, the conductive contact 181-2 is disposed on or within the field plate holder 173. In some embodiments, the field plate holder 173 covers or directly contacts the lateral surface and bottom surface of the conductive contact 181-2. The conductive contact 181-2 is spaced apart from the ILD 172 by the field plate holder 173. The conductive contact 181-2 is vertically spaced apart from the substrate 110 by the field plate holder 173 and the etch stop layer 170-2. In some embodiments, the conductive contact 182-2 is disposed on or within the field plate holder 174. The field plate holder 174 is closer to the gate structure 120-2 than the field plate holder 173 is. In some embodiments, the conductive contact 180 (or other contacts) is free of being in contact with a field plate holder. In some embodiments, the length L1 of the conductive contact 182-2, which is defined by the upper surface and the lower surface of the conductive contact 182-2, is less than the length L2 of the field plate holder 174, which is defined by the upper surface and the lower surface of the field plate holder 174.

In some embodiments, each of the field plate holders 173 and 174 has a substantially U-shaped profile. In some embodiments, each of the upper surface of the field plate holders 173 and 174 is substantially aligned with or coplanar with the upper surface of the ILD 172. For example, a surface 173s1 of the field plate holder 173 is substantially aligned with or coplanar with of a surface 172s1 of the ILD 172. Although FIG. 2 illustrates that the lower surface, opposite to the upper surface, of the field plate holder 173 (or 174) is substantially aligned with or coplanar with of the upper surface of the etch stop layer 170-2, the lower surface of the field plate holder 173 (or 174) slightly extends into the etch stop layer 170-2 in other embodiments. In some embodiments, the slope of the lateral surface, which contacts the ILD 172, of the field plate holder 173 is different from the slope of the lateral surface of the conductive contact 181-2. Although FIG. 2 illustrates that the outer lateral surface of the field plate holder 173 (or 174) is substantially orthogonal to the upper surface of the etch stop layer 170-2, the outer lateral surface of the field plate holder 173 (or 174) is slanted with respect to the upper surface of the etch stop layer 170-2 in other embodiments. In some embodiments, the filed plate holder 174 has a base 1741 and ax extension 1742 extending between the base 1741 and the surface 172s1 of the ILD 172. In some embodiments, the extension 1742 is tapered along a direction far away from the substrate 110.

In some embodiments, each of the field plate holders 173 and 174 may include a dielectric material, such as a nitride-containing material, semiconductor-containing material, metallic halide, metallic nitride, or other materials which is more resistant to an etchant (e.g., halide-containing etchant) compared to oxide-containing material. In some embodiments, the material of the field plate holders 173 and 174 includes silicon nitride, silicon oxynitride, silicon carbonitride, silicon, silicon germanium, titanium halide (e.g., TiFₓ, TiClₓ, TiBrₓ, or TiIₓ), aluminum halide (e.g., AlFₓ, AlClₓ, AlBrₓ, or AlIₓ), zirconium halide (e.g., ZrFₓ, ZrClₓ, ZrBrₓ, or ZrIₓ), hafnium halide (e.g., HfFₓ, HfClₓ, HfBrₓ, or HfIₓ), or other suitable materials.

The process of defining openings for conductive contacts and field plates involves etching the ILD. A stack of nitride/oxide/nitride layers is used as an etch stop structure in a comparative semiconductor device to define the openings for accommodating field plates. In some cases, over-etching may occur at the corner of the etch stop structure, particularly where it abuts a gate structure, due to its smaller packing density. This may lead to the exposure of a substrate by said opening after an etching process, resulting in electrical leakage. In the embodiments of the present disclosure, a field plate holder is used to accommodate a field plate. The field plate holder and the ILD exhibit significantly improved etching selectivity to a specific etchant (e.g., halide-containing etchant) in comparative to a conventional device. As a result, the aforesaid issues can be addressed.

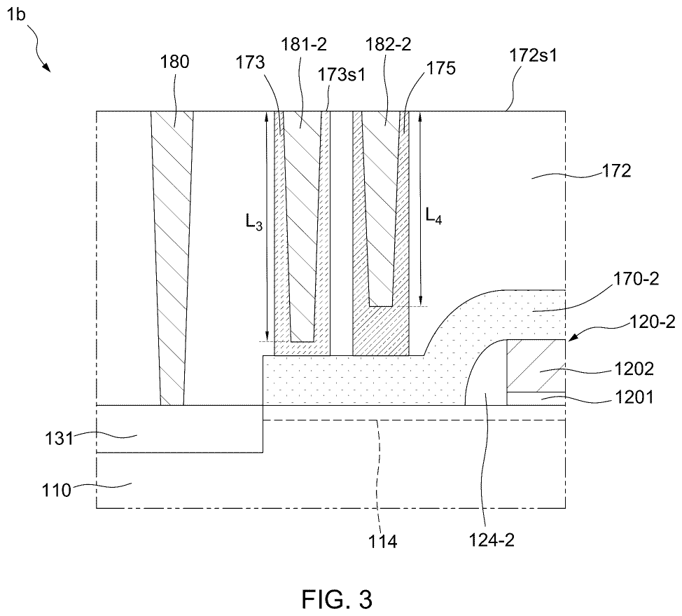

FIG. 3 illustrates a cross-sectional view of a semiconductor device 1b, in accordance with some embodiments of the present disclosure. In some embodiments, the semiconductor device 1b has a structure similar to that of the semiconductor device 1a, and one of the differences between them is that the semiconductor device 1b includes a field plate holder 175. In some embodiments, the field plate holder 175 surrounds and supports the conductive contact 182-2. The field plate holder 175 is closer to the gate structure 120-2 than the field plate holder 173 is. In some embodiments, the material of the field plate holder 175 is different from that of the field plate holder 173. In some embodiments, the field plate holder 175 is more resistive to an etchant (e.g., halide-containing etchant) than the field plate holder 173 is. For example, the field plate holder 175 includes a nitride-containing material (e.g., silicon nitride), and the field plate holder 173 includes a semiconductor-containing material (e.g., silicon germanium). In some embodiments, the length L3 of the conductive contact 181-2, which can be defined by a distance between the upper surface and the lower surface of the conductive contact 181-2, is different from the length L4 of the conductive contact 182-2, which can be defined by a distance between the upper surface and the lower surface of the conductive contact 182-2. In some embodiments, the distance between the lower surface of the conductive contact 182-2 and the substrate 110 is greater than the distance between the lower surface of the conductive contact 181-2 and the substrate 110. By arranging different materials of the field plate holders, the length of the field plate can be modified or controlled. As a result, the breakdown voltage capability of the semiconductor device 1c may be enhanced.

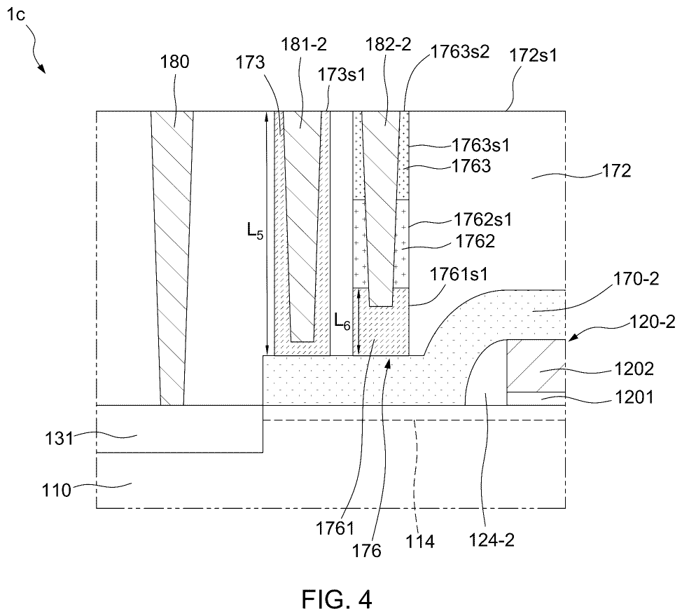

FIG. 4 illustrates a cross-sectional view of a semiconductor device 1c, in accordance with some embodiments of the present disclosure. In some embodiments, the semiconductor device 1c has a structure similar to that of the semiconductor device 1a, and one of the differences between them is that the semiconductor device 1c includes a field plate holder 176 accommodating the conductive contact 182-2. In some embodiments, the field plate holder 176 includes two or more materials. For example, the field plate holder 176 includes layers 1761, 1762, and 1763 with different materials. The layer 1761 is disposed on the etch stop layer 170-2. The layer 1762 is disposed on the layer 1761. The layer 1763 is disposed on the layer 1762. The conductive contact 182-2 penetrates the layers 1762 and 1763. In some embodiments, the layer 1761 defines a recess accommodating the conductive contact 182-2.

In some embodiments, the material of the layer 1761 is the same as that of the field plate holder 173. In some embodiments, the material of the layer 1762 and/or layer 1763 is more resistive to an etchant (e.g., halide-containing etchant) than the layer 1761 is. For example, the layer 1761 includes a semiconductor-containing material (e.g., silicon germanium), the layer 1762 includes a nitride-containing material (e.g., silicon nitride), and the layer 1763 includes a metallic material (e.g., metallic halide or metallic nitride). In some embodiments, the length of the conductive contact 181-2 is different from that of the conductive contact 182-2. In some embodiments, a surface 1761s1 (or lateral surface or side) of the layer 1761 is substantially aligned with a surface 1762s1 (or lateral surface or side) of the layer 1762. In some embodiments, the surface 1762s1 (or lateral surface or side) of the layer 1762 is substantially aligned with a surface 1763s1 (or lateral surface or side) of the layer 1763. In some embodiments, the surface 173s1 of the field plate holder 173 is substantially aligned with or coplanar with a surface 1763s2 (or upper surface) of the layer 1763. In some embodiments, the length L5, defined by the upper surface and the lower surface, of the field plate holder 173 is greater than the length L6, defined by the upper surface and the lower surface, of the layer 1761.

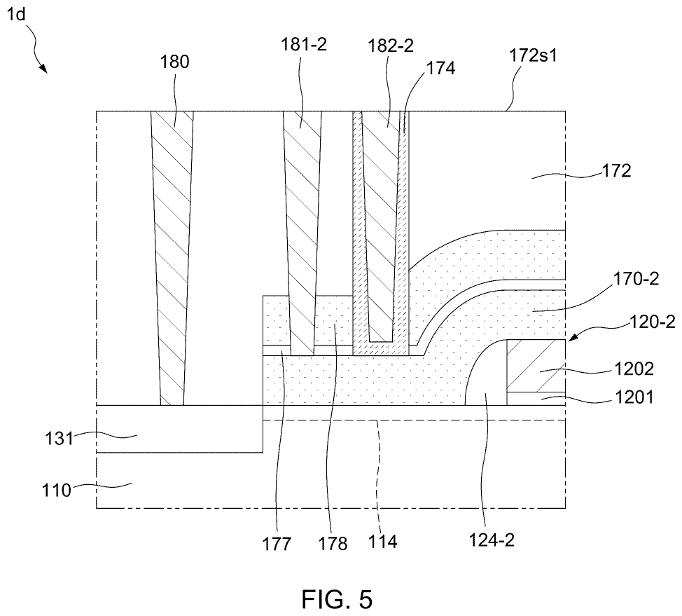

FIG. 5 illustrates a cross-sectional view of a semiconductor device 1d, in accordance with some embodiments of the present disclosure. In some embodiments, the semiconductor device 1d has a structure similar to that of the semiconductor device 1a, and one of the differences between them is that the semiconductor device 1d includes a dielectric layer 177 and ant etch stop layer 178. The dielectric layer 177 is disposed on the etch stop layer 170-2. In some embodiments, the dielectric layer 177 includes an oxygen-containing material, such as silicon oxide, tetraethylorthosilicate (TEOS) oxide, or other suitable materials. The etch stop layer 178 is disposed on the dielectric layer 177. In some embodiments, the material of the etch stop layer 178 is the same as or similar to that of the etch stop layer 170-2. In some embodiments, the lower surface of the conductive contact 181-2 is in contact with the etch stop layer 170-2. The conductive contact 181-2 penetrates the dielectric layer 177 and the etch stop layer 178. In some embodiments, the conductive contact 182-2 penetrates the dielectric layer 177 and the etch stop layer 178. The filed plate holder 174 penetrates the dielectric layer 177 and the etch stop layer 178. The conductive contact 182-2 is spaced apart from the dielectric layer 177. The conductive contact 182-2 is spaced apart from the dielectric layer 177. The etching stop layers 170-2, the dielectric layer 177, and the etch stop layer 178 collectively function as an etch stop structure that prevent over-etching of the opening for accommodating the field plate 181-2.

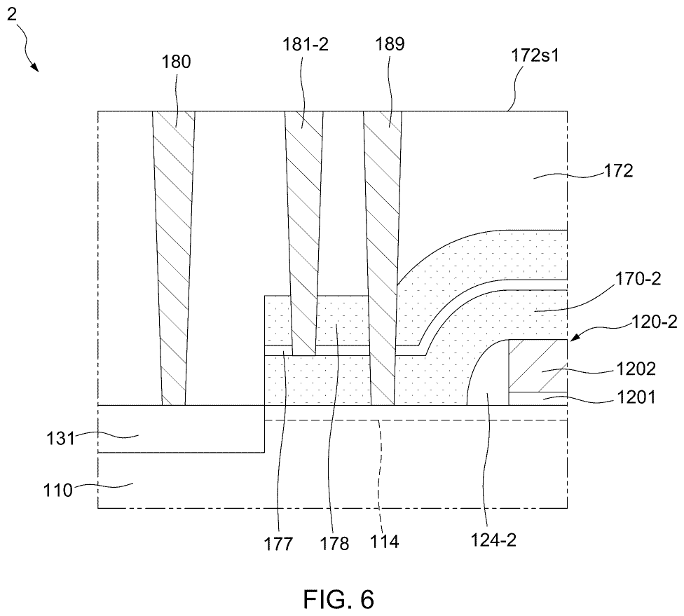

FIG. 6 illustrates a cross-sectional view of a comparative semiconductor device 2, in accordance with some embodiments of the present disclosure. The semiconductor device 2 includes a conductive contact 189 which abuts the corner of a stack of the etch stop layer 170-2, the dielectric layer 177, and the etch stop layer 178. In this case, when an etching technique is performed, an over-etching occurs in the region near the corner of the stacked structure. As a result, the conductive contact 189 may be connected to the substrate 110, resulting an electrical leakage.

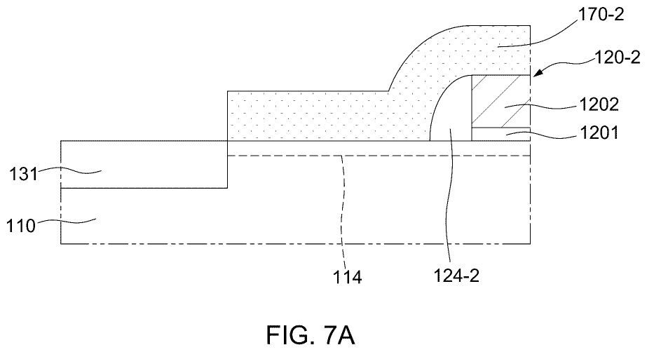

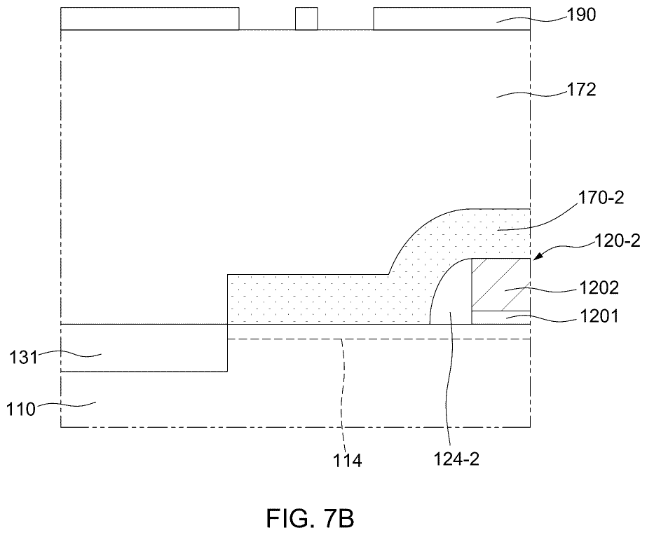

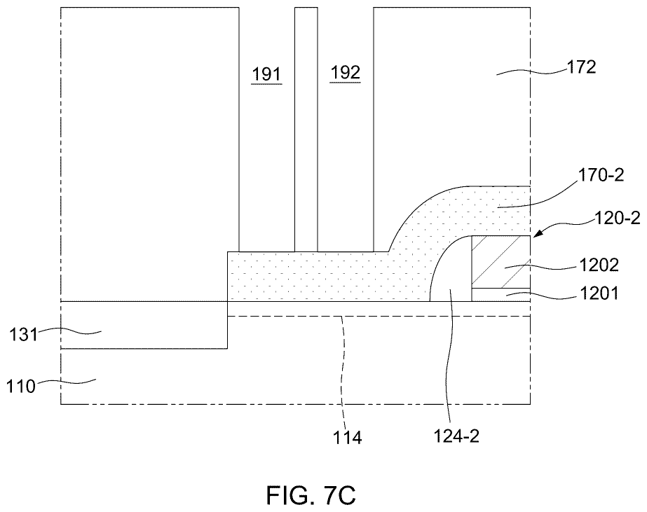

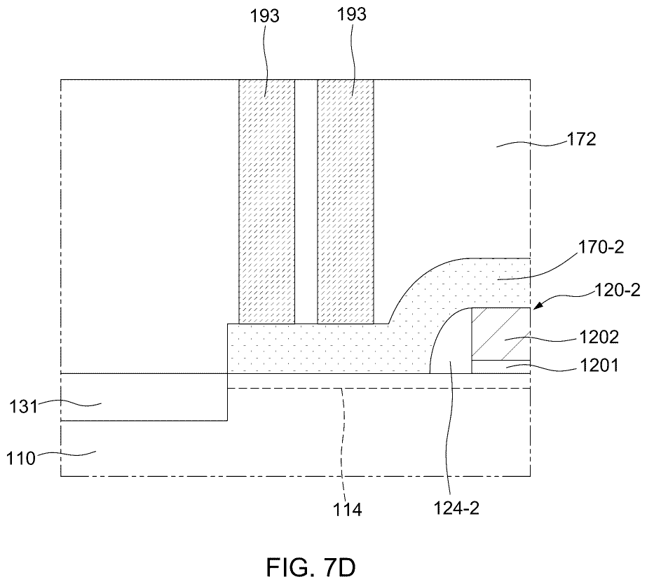

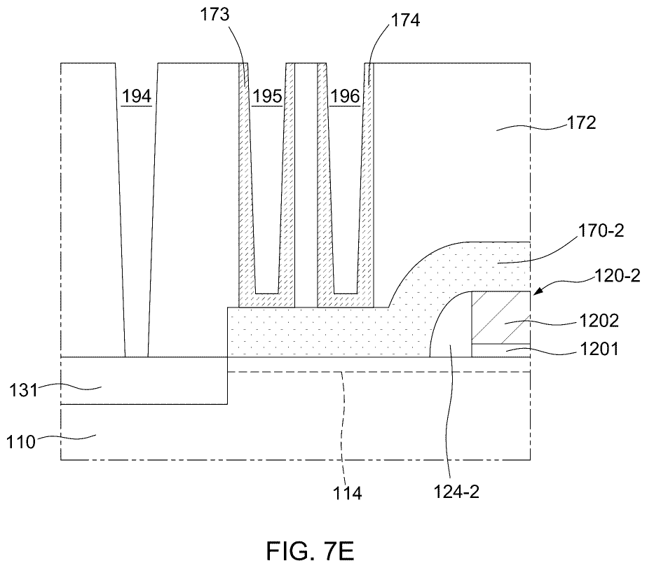

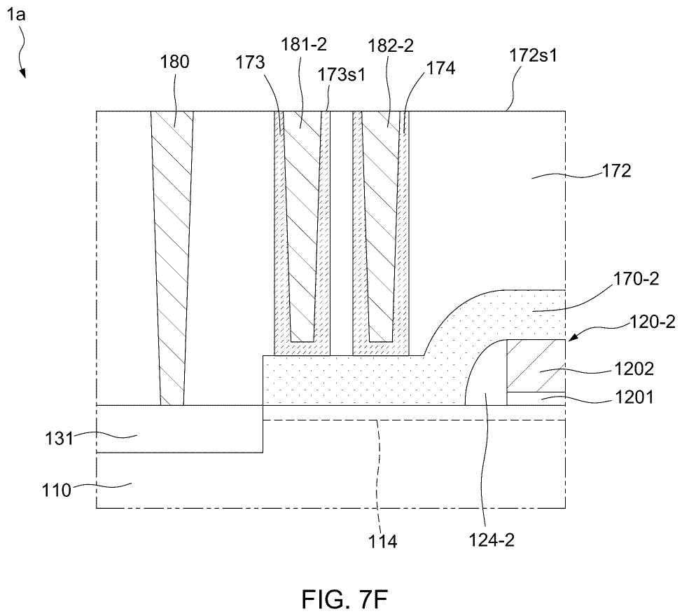

FIG. 7A, FIG. 7B, FIG. 7C, FIG. 7D, FIG. 7E, and FIG. 7F illustrate various stages of manufacturing a semiconductor device, in accordance with some embodiments of the present disclosure.

Referring to FIG. 7A, the substrate 110 is provided. The gate structure 120-2 is formed. The spacer 124-2 is formed on a sidewall of the gate structure 120-2. The doped region 131 is formed within the substrate 110. The etch stop layer 170-2 is conformally formed to cover the upper surface of the gate electrode 1202, the spacer 124-2, and the substrate 110. The etch stop layer 170-2 may be patterned to expose the doped region 131. The gate dielectric 1201, gate electrode 1202, the spacer 124-2, and the etch stop layer 170-2 may be formed by a deposition technique, such as chemical vapor deposition (CVD), physical vapor deposition (PVD), atomic layer deposition (ALD), and other suitable techniques.

Referring to FIG. 7B, the ILD 172 is formed to cover the etch stop layer 170-2 and the substrate 110. In some embodiments, the ILD 172 is formed by CVD, PVD, ALD, and other suitable techniques. A photosensitive material 190 is formed on the ILD 172 to define the location of field plate holders. The photosensitive material 190 includes a photoresist or other suitable materials.

Referring to FIG. 7C, an etching technique is performed to pattern the ILD 172. The photosensitive material 190 is removed. Openings 191 and 192 are formed over the etch stop layer 170-2. The etch stop layer 170-2 is exposed by the openings 191 and 192.

Referring to FIG. 7D, a dielectric material 193 is formed to fill the openings 191 and 192. In some embodiments, the dielectric material 193 is configured to form the field plate holders. The dielectric material 193 is formed by CVD, PVD, ALD, and other suitable techniques. A chemical mechanical polishing (CMP) or other suitable techniques may be performed to remove excess portions of the dielectric material 193 over the ILD 172. As a result, the upper surface of the dielectric material 193 is substantially aligned with that of the ILD 172.

Referring to FIG. 7E, an etching technique is performed to form openings 194, 195, and 196. A portion of the ILD 172 and a portion of the dielectric material 193 are removed. The doped region 131 is exposed by the opening 194. The openings 195 and 196 penetrate a portion of the dielectric material 193. As a result, the field plate holders 173 and 174 are produced. In some embodiments, a halide-containing etchant is utilized. In some embodiments, the halide-containing etchant includes CF₄, C₂F₆, C₃F₈, C₄F₁₀, or other suitable etchants. Because the etchant containing halide has a higher etching rate for the ILD 172 than for the field plate holder 174 (or 173), the depth of the opening 194 is greater than that of the field plate holder 174 (or 173). Further, the profile of the field plate holder 174 does not have a corner profile as described in the semiconductor device 2. This helps to prevent over-etching of the opening 196.

Referring to FIG. 7F, the conductive contacts 180, 181-2, and 182-2 are formed. The conductive contacts 180, 181-2, and 182-2 are formed by PVD, CVD, ALD, and other suitable techniques. As a result, a semiconductor device (e.g., the semiconductor device 1a) is produced.

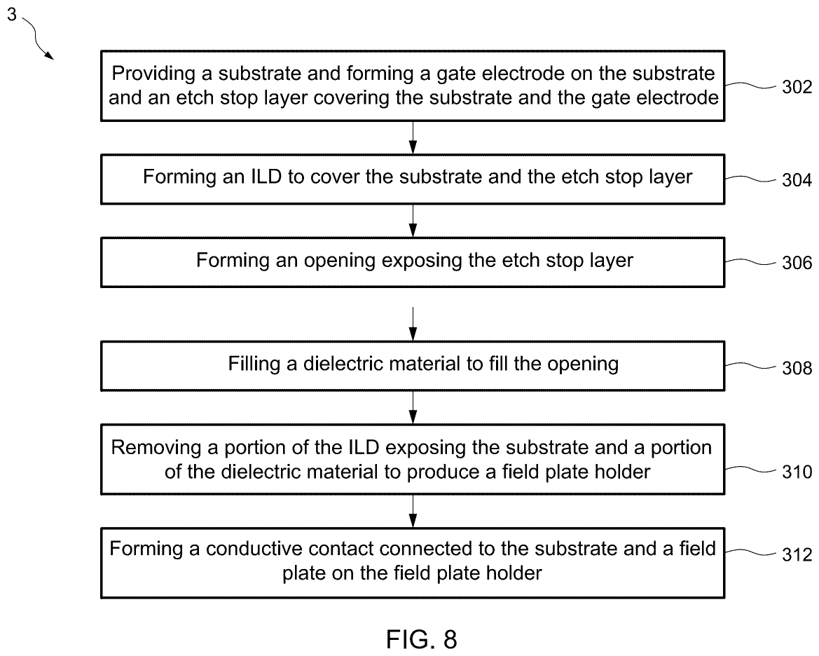

FIG. 8 is a flow chart illustrating a method 3 for manufacturing a semiconductor device according to various aspects of the present disclosure.

The method 3 begins with operation 302 in which a substrate is provided. A gate structure is formed on the substrate. An etch stop layer is formed to cover the gate structure and the substrate.

The method 3 continues with operation 304 in which an ILD is formed to cover the substrate and the etch stop layer.

The method 3 continues with operation 306 in which an etching technique is performed to form an opening over the etch stop layer.

The method 3 continues with operation 308 in which a dielectric material is formed to fill the opening.

The method 3 continues with operation 310 in which an etching technique is performed to remove a portion of the ILD to expose the substrate and a portion of the dielectric material to produce a field plate holder.

The method 3 continues with operation 312 in which a conductive contact is formed to be connected to the substrate and a field plate is formed within the field plate holder.

The method 3 is merely an example, and is not intended to limit the present disclosure beyond what is explicitly recited in the claims. Additional operations can be provided before, during, and after the method 3, and some operations described can be replaced, eliminated, or moved around for additional embodiments of the method.

Some embodiments of the present disclosure provide a semiconductor device. The semiconductor device includes a substrate, a gate electrode, a source/drain feature, an interlayer dielectric (ILD), a first field plate holder, and a first field plate. The gate electrode is disposed on the substrate. The source/drain feature is disposed within the substrate and defines a drift region within the substrate. The ILD covers the gate electrode and the substrate. The first field plate holder penetrates the ILD and is disposed over the drift region. The first field plate is disposed on the first field plate holder.

Some embodiments of the present disclosure provide a method of manufacturing a semiconductor device. The method includes: providing a substrate; forming a gate electrode on the substrate; forming an etch stop layer to cover the substrate and the gate electrode; forming an interlayer dielectric (ILD) to cover the etch stop layer; patterning the ILD to form a first opening; forming a field plate holder within the first opening of the ILD; and forming a field plate on the field plate holder.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a gate electrode disposed on the substrate;
an etch stop layer conformally extending from an upper surface of the gate electrode to an upper surface of the substrate;
an interlayer dielectric (ILD) covering the gate electrode and the etch stop layer;
a field plate holder embedded within the ILD and spaced apart from the substrate by the etch stop layer; and
a field plate supported by the field plate holder.

2. The semiconductor device of claim 1, wherein an upper surface of the field plate holder is substantially aligned with an upper surface of the ILD.

3. The semiconductor device of claim 1, wherein the field plate holder comprises a semiconductor-containing material, a nitride-containing material, and a combination thereof.

4. The semiconductor device of claim 1, wherein the field plate is surrounded by the field plate holder.

5. The semiconductor device of claim 1, wherein the field plate is spaced apart from the substrate by the field plate holder and the etch stop layer.

6. The semiconductor device of claim 1, further comprising:
a source/drain feature disposed within the substrate and defining a drift region within the substrate, and the field plate holder is disposed over the drift region.

7. The semiconductor device of claim 1, wherein the field plate holder comprises a first dielectric material layer and a second dielectric material layer on the first dielectric material layer.

8. The semiconductor device of claim 7, wherein the first dielectric material layer defines a recess accommodating the field plate.

9. The semiconductor device of claim 7, wherein the first dielectric material layer is free from vertically overlapping the gate electrode.

10. The semiconductor device of claim 1, wherein the field plate holder has a substantially U-shaped profile.

11. A semiconductor device, comprising:
a substrate;
a gate electrode disposed on the substrate;
a source/drain (S/D) feature disposed within the substrate and defining a drift region within the substrate;
an interlayer dielectric (ILD) covering the gate electrode and the substrate;
a first field plate holder penetrating the ILD and disposed over the drift region; and
a first field plate disposed on the first field plate holder.

12. The semiconductor device of claim 11, wherein the first field plate is spaced apart from the ILD by the first field plate holder.

13. The semiconductor device of claim 12, wherein the first field plate is spaced apart from the substrate by the first field plate holder.

14. The semiconductor device of claim 11, further comprising:
a second field plate holder embedded within the ILD and disposed over the drift region; and
a second field plate disposed within the second field plate holder, wherein a bottom of the first field plate is at an elevation different from that of the second field plate with respect to an upper surface of the substrate.

15. The semiconductor device of claim 14, wherein a material of the first field plate holder is different from that of the second field plate holder.

16. The semiconductor device of claim 11, wherein the first field plate holder is free from vertically overlapping the S/D feature.

17. The semiconductor device of claim 11, further comprising:
an etch stop layer disposed between the first field plate holder and the substrate.

18. The semiconductor device of claim 11, wherein an upper surface of the first field plate holder is substantially aligned with an upper surface of the ILD.

19. A method of manufacturing a semiconductor device, comprising:
providing a substrate;
forming a gate electrode on the substrate;
forming an etch stop layer to cover the substrate and the gate electrode;
forming an interlayer dielectric (ILD) to cover the etch stop layer;
patterning the ILD to form a first opening;
forming a field plate holder within the first opening of the ILD; and
forming a field plate on the field plate holder.

20. The method of claim 19, wherein forming the field plate holder comprises:
forming a dielectric material within the opening of the ILD; and
removing a portion of the dielectric material to form the field plate holder.
